(19) United States
(12) Patent Application Publication
(10) Pub. No.: US 2026/0245023 A1
(43) Pub. Date: Aug. 20, 2026

(54) Transport Facility

(71) Applicant: Daifuku Co., Ltd., Osaka-shi (JP)

(72) Inventor: Kengo Ikedo, Komaki-shi (JP)

(21) Appl. No.: 19/540,860

(22) Filed: Feb. 16, 2026

(30) Foreign Application Priority Data
Feb. 17, 2025 (JP) 2025-023105

(51) Int. Cl. G06Q 10/08; H10P 72/30

(52) U.S. Cl. CPC G06Q 10/08; H10P 72/3218; H10P 72/3404; H10P 72/3408

(57) ABSTRACT

In a transport facility, a control system executes assignment processing for assigning a first task, which is one of the tasks, to a movable body; wait processing for, after executing the assignment processing, causing the movable body to wait for a waiting time before executing the first task; assignment determination processing for, during the waiting time, determining whether or not to assign a second task, which is the other task, to the movable body; consecutive transport processing for, in a case of determining to assign the second task to the movable body, causing the movable body to execute a load transport task and a unload transport task consecutively; and single transport processing for, in a case of determining not to assign the second task to the movable body, causing the movable body to execute the first task after the waiting time elapses.

### CROSS-REFERENCE TO RELATED APPLICATION

This application claims priority to Japanese Patent Application No. 2025-023105 filed February 17, 2025, the disclosure of which is hereby incorporated by reference in its entirety.

### BACKGROUND OF THE INVENTION

### Field of the Invention

The present invention relates to a transport facility having a movable body that transports an article, a storage device that stores a plurality of articles, and a control system that controls the movable body.

### Description of Related Art

An example of such a transport facility is disclosed in Japanese Patent Application Laid-Open No. 2013-214654 (hereinafter referred to as “JP 2013-214654”). In the following description of the related art, the reference symbols used in JP 2013-214654 will be cited in parentheses.

In a transport facility (1) of JP 2013-214654, a storage device (3) includes a loading section (32A) for receiving articles (20) and an unloading section (32B) for unloading articles (20).

The movable body (2) is configured to be able to execute a load transport task for transferring an article (20) received at a transport origin to the loading section (32A), and an unload transport task for receiving an article (20) from the unloading section (32B) and transporting the received article (20)

In the transport facility (1) of JP 2013-214654, when tasks are assigned to the movable body (2) by a control system (12), the movable body (2) executes the assigned tasks in sequence. However, there are cases where the travel distance of the movable body (2) becomes long, and the efficiency of transport of articles (20) by the movable body (2) may be reduced.

### SUMMARY OF THE INVENTION

Therefore, it is desirable to realize a transport facility that can easily shorten the travel distance of the movable body and easily increase the efficiency of article transport performed by the movable body.

In view of the above, a characteristic configuration of a transport facility according to an aspect of the present invention lies in a transport facility including:

a movable body configured to transport an article;

a storage device including at least one loading section and at least one unloading section, and configured to store a plurality of articles; and

a control system configured to control the movable body,

the storage device being further configured to receive an article from the movable body via the loading section and store the received article, and transfer the stored article from the unloading section to the movable body,

the control system being further configured to cause the movable body to execute an unload transport task in which the movable body receives an article from the unloading section and transports the received article to a transport destination, and a load transport task in which the movable body transfers, to the loading section, an article received at a transport origin, and

the control system being further configured to execute

assignment processing of assigning a first task, which is a first one of the unload transport task and the load transport task, to the movable body,

wait processing of, after executing the assignment processing, causing the movable body to wait for a predetermined waiting time before executing the first task,

assignment determination processing of, during the waiting time, determining whether or not to assign a second task, which is a second one of the unload transport task and the load transport task, to the movable body,

consecutive transport processing of, in response to the control system determining to assign the second task to the movable body in the assignment determination processing, causing the movable body to execute the load transport task and the unload transport task consecutively, and

single transport processing of, in response to the control system determining not to assign the second task to the movable body in the assignment determination processing, causing the movable body to execute the first task after the waiting time elapses.

According to this characteristic configuration, when consecutive transport processing is executed, the movable body can execute the load transport task and the unload transport task consecutively. This makes it easier to shorten the travel distance traveled by the movable body, and to increase the efficiency of transport of articles by the movable body.

Also, the time for which the execution of the first task is put on hold in the wait processing is limited to the waiting time, thereby making it possible to avoid the case where the first task is not executed for a long period of time even when single transport processing is executed. This makes it possible to minimize the decrease in the efficiency of transport of articles by the movable body.

### BRIEF DESCRIPTION OF THE DRAWINGS

FIG. 1 is a diagram illustrating an overall configuration of a transport facility according to an embodiment.

FIG. 2 is a diagram illustrating a configuration of a movable body included in the transport facility according to the embodiment.

FIG. 3 is a control block diagram of the transport facility according to the embodiment.

FIG. 4 is a diagram illustrating an example of control of the movable body performed by a control system.

FIG. 5 is a diagram illustrating an example of control of the movable body performed by the control system.

FIG. 6 is a diagram illustrating an example of control of the movable body performed by the control system.

FIG. 7 is a diagram illustrating an example of control of the movable body performed by the control system.

FIG. 8 is a diagram illustrating an example of control of the movable body performed by the control system.

FIG. 9 is a flowchart illustrating an example of control of the movable body performed by the control system.

### DESCRIPTION OF THE INVENTION

A transport facility 100 according to an embodiment will be described below with reference to the drawings.

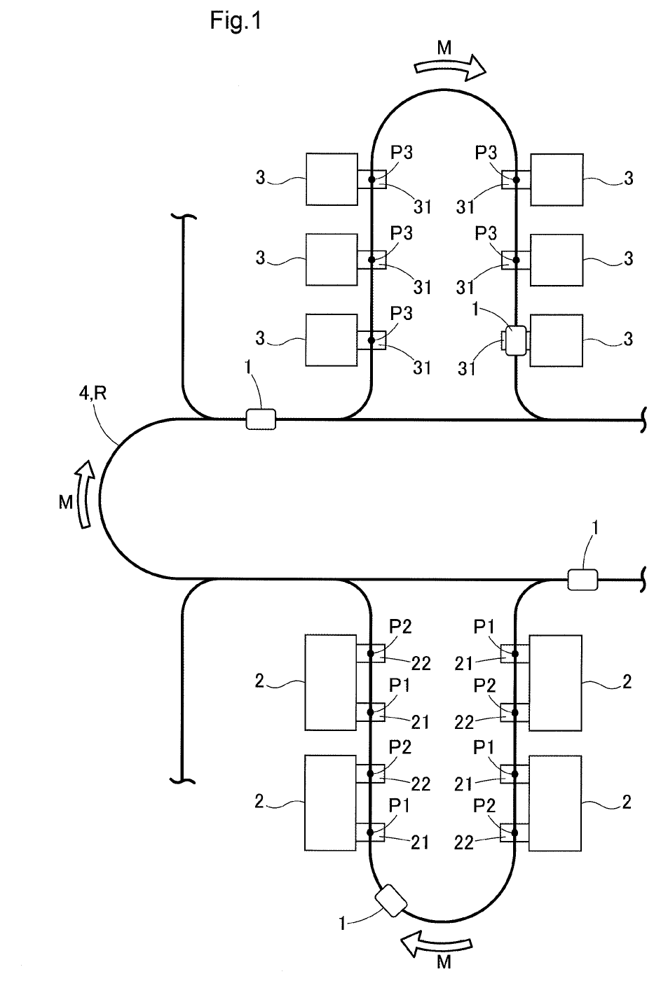

As shown in FIG. 1, the transport facility 100 includes a movable body 1 and a storage device 2. In the present embodiment, the transport facility 100 includes a plurality of movable bodies 1 and a plurality of storage devices 2. Also, in the present embodiment, the transport facility 100 further includes a plurality of processing devices 3.

The movable body 1 transports an article W. In the present embodiment, the movable body 1 moves in a predetermined movement direction M along a predetermined movement route R. In the present embodiment, the movement route R is formed by a rail 4 suspended from the ceiling. The movable body 1 is an overhead transport vehicle that travels and transports the article W along a travel path P while being guided by the rail 4. In the present embodiment, the article W is a FOUP (Front Opening Unified Pod) that accommodates a wafer.

The storage device 2 is a device that stores a plurality of articles W. The storage device 2 includes a loading section 21 and an unloading section 22. In the present embodiment, in the storage device 2, the unloading section 22 is arranged downstream of the loading section 21 in the movement direction M.

The storage device 2 is configured to receive an article W from the movable body 1 at the loading section 21 and store the received article, and to deliver a stored article W from the unloading section 22 to the movable body 1. Therefore, the movable body 1 is configured to stop at a predetermined loading position P1 on the movement route R for transfer of an article W with the loading section 21, and to stop at a predetermined unloading position P2 on the movement route R for transfer of an article W with the unloading section 22.

The processing device 3 is a device that processes the article W. In the present embodiment, the processing device 3 takes a wafer out from the FOUP and performs various types of processing on the wafer, such as thin film formation, photolithography, and etching.

In the present embodiment, the processing device 3 includes a load port 31. After receiving a FOUP from the movable body 1 at the load port 31, the processing device 3 performs the above-mentioned processing on a wafer taken out of the FOUP. The processing device 3 then delivers the processed wafer from the load port 31 to the movable body 1. Therefore, in the present embodiment, the movable body 1 is configured to stop at a predetermined transfer position P3 on the movement route R and perform transfer of an article W with the processing device 3 (here, the load port 31).

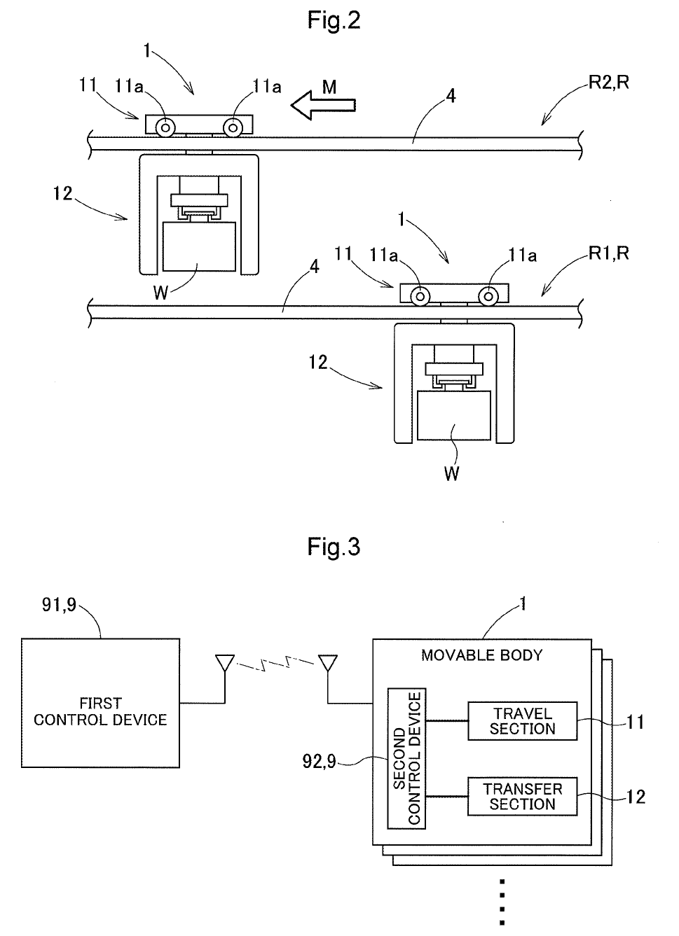

As shown in FIG. 2, in the present embodiment, the movable body 1 includes a travel section 11 and a transfer section 12.

The travel section 11 includes travel wheels 11a that roll on the rail 4. In the present embodiment, at least one of the travel wheels 11a is rotated by driving force from a travel motor (not shown).

The transfer section 12 transfers the article W to and from transfer target locations including the loading section 21, the unloading section 22, and the load port 31. Although detailed description will be omitted, the transfer section 12 includes, for example, a holding section that holds the article W, a lifting section that moves the holding section up and down relative to the travel section 11, a horizontal movement section that moves the holding section horizontally relative to the travel section 11, and a rotating section that rotates the holding section relative to the travel section 11 around a rotation axis extending in the vertical direction. The transfer section 12 is not limited to the above configuration, and need only have a necessary configuration for transfer of the article W to and from the above transfer target locations.

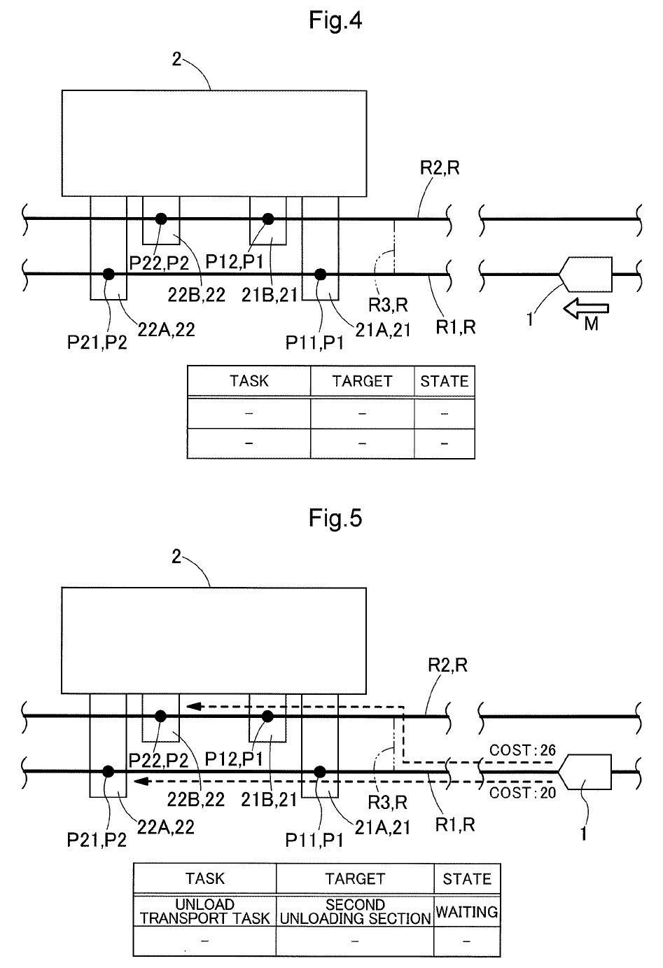

In the present embodiment, the movement route R includes a first layer route R1, a second layer route R2 located above the first layer route R1, and a connecting route R3 (see FIG. 4, etc.) that connects the first layer route R1 and the second layer route R2 to each other. In the present embodiment, the first layer route R1 is a route traveled by a movable body 1 to which a task with a relatively short travel distance is assigned. The second layer route R2 is a route traveled by a movable body 1 to which a task that involves a relatively long travel distance is assigned. Also, the connecting route R3 is constituted by a lifter that raises and lowers the movable body 1, a rail that is inclined relative to the horizontal direction, and the like.

Although not shown, in the present embodiment, the number of transfer positions P3 set on the second layer route R2 is smaller than the number of transfer positions P3 set on the first layer route R1. In this example, no transfer position P3 is set on the second layer route R2.

As shown in FIG. 3, the transport facility 100 includes a control system 9 that controls the movable body 1. The control system 9 is configured by a computer, and the functions of the control system 9 are realized by cooperation between hardware and software. In the present embodiment, the control system 9 includes a first control device 91 provided at a predetermined location in the transport facility 100, and second control devices 92 respectively provided in the movable bodies 1. The first control device 91 and the second control devices 92 are configured to be able to communicate with each other wirelessly.

The first control device 91 transmits control commands to each of the second control devices 92. The second control devices 92 control the travel sections 11 and the transfer sections 12 of the movable bodies 1 based on control commands from the first control device 91.

As shown in FIG. 4, in the present embodiment, the loading sections 21 include a first loading section 21A at which article W transfer is performed with a movable body 1 located on the first layer route R1, and a second loading section 21B at which article W transfer is performed with a movable body 1 located on the second layer route R2. Therefore, in the present embodiment, the loading positions P1 include a first loading position P11 for the transfer of an article W between the movable body 1 and the first loading section 21A, and a second loading position P12 for the transfer of an article W between the movable body 1 and the second loading section 21B.

Also, in the present embodiment, the unloading sections 22 include a first unloading section 22A at which article W transfer is performed with a movable body 1 located on the first layer route R1, and a second unloading section 22B at which article W transfer is performed with a movable body 1 located on the second layer route R2. Therefore, in the present embodiment, the unloading positions P2 include a first unloading position P21 for the transfer of an article W between the movable body 1 and the first unloading section 22A, and a second unloading position P22 for the transfer of an article W between the movable body 1 and the second unloading section 22B.

The control system 9 is configured to cause a movable body 1 to execute an unload transport task in which the movable body 1 receives an article W from an unloading section 22 and transports it to a transport destination, and a load transport task in which the movable body 1 passes an article W received from a transport origin to a loading section 21. Note that the transport destination in the unload transport task and the transport origin in the load transport task are, for example, the load port 31 of a processing device 3, a conveyor, or the like to or from which an article W is transferred by the movable body 1. Also, the transport destination in the unload transport task may be the loading section 21 of another storage device 2 (a storage device 2 different from the storage device 2 that includes the unloading section 22 from which the movable body 1 receives the article W in the unload transport task). The transport origin in the load transport task may be the unloading section 22 of another storage device 2.

An example of control of the movable body 1 by the control system 9 will be described below with reference to FIGS. 4 to 9. Note that in the following description, either the unload transport task or the load transport task will be referred to as the “first task”, and the other will be referred to as the “second task”.

As shown in FIG. 4, when control starts, no task has been assigned to the movable body 1. The movable body 1 is located on the first layer route R1. Furthermore, the movable body 1 is not holding an article W.

The control system 9 first executes assignment processing to assign a first task to the movable body 1. In the example shown in FIG. 5, in the assignment processing, an unload transport task for the second unloading section 22B is set as the first task. The state in which a task has been assigned to the movable body 1 refers to a state before the task is actually executed.

In this example, the control system 9 is configured to use costs respectively set for operations of the movable body 1, including the traveling of the movable body 1 and the transfer of the article W to and from the loading section 21 and the unloading section 22, and to assign the unload transport task and the load transport task to the movable body 1 such that the cost is minimized. The aforementioned costs include, for example, a cost corresponding to the travel distance traveled by the movable body 1, a cost corresponding to the transfer operation performed by the movable body 1, a cost corresponding to the structure and shape of the movement route R, and a cost corresponding to the presence and status of other movable bodies 1.

Here, in the example shown in FIG. 5, the cost required for the unload transport task for the first unloading section 22A (here, a cost of 20) is lower than the cost required for the unload transport task for the second unloading section 22B (here, a cost of 26). Therefore, normally, the control system 9 would assign the unload transport task for the first unloading section 22A to the movable body 1. However, in the assignment processing of this example, the control system 9 assigns the unload transport task for the second unloading section 22B to the movable body 1 as the first task, without taking the cost into consideration. In this example, the cost required for the unload transport task for the first unloading section 22A is lower than the cost required for the unload transport task for the second unloading section 22B because the cost for the movable body 1 to travel along the connecting route R3 is set relatively high.

Also, if the transport distance of the article W in the unload transport task assigned to movable body 1 is less than a determination distance D, that is, if the distance that movable body 1 transports the article W in the unload transport task is relatively short, it is preferable in the assignment processing to set the unload transport task for the first unloading section 22A as the first task. The determination distance D is determined based on the case where the movable body 1 moves to another area or building in the unload transport task, for example.

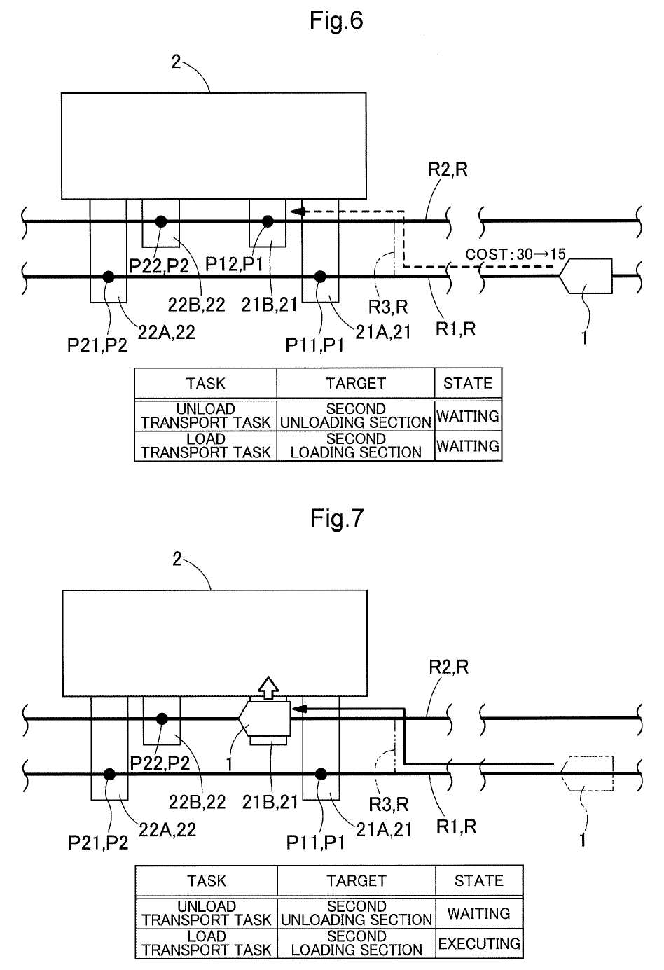

As shown in FIG. 6, after executing the assignment processing, the control system 9 executes wait processing for causing the movable body 1 to wait for a predetermined waiting time T before executing the first task (here, the unload transport task for the second unloading section 22B).

Also, when the first task is the unload transport task, if the transport destination of the article W in the unload transport task is another storage device 2, it is preferable to set the waiting time T longer than in the case where the transport destination is the processing device 3.

Also, in the assignment processing, it is preferable to execute wait processing when the first task is an unload transport task for the second unloading section 22B or a load transport task for the second loading section 21B, and not execute wait processing when the first task is an unload transport task for the first unloading section 22A or a load transport task for the first loading section 21A.

During the waiting time T, the control system 9 executes assignment determination processing to determine whether or not to assign the second task to the movable body 1. In the example shown in FIG. 6, in the assignment determination processing, the load transport task for the second loading section 21B is set as the second task.

During the waiting time T, the control system 9 determines the task to be assigned to the movable body 1 based on the costs, as described above. In this example, during the waiting time T, the control system 9 executes cost adjustment processing to set the cost required to execute the second task (here, the load transport task for the second loading section 21B) lower than that during the time excluding the waiting time T (here, the cost required to execute the load transport task for the second loading section 21B is halved from 30 to 15). This increases the possibility that the second task (here, the load transport task for the second loading section 21B) will be assigned to the movable body 1 during the waiting time T. In the cost adjustment processing, one of the various costs described above may be reduced, or a plurality of such costs may be reduced.

In the example shown in FIG. 6, during the waiting time T, the control system 9 assigns the load transport task for the second loading section 21B to the movable body 1 as the second task.

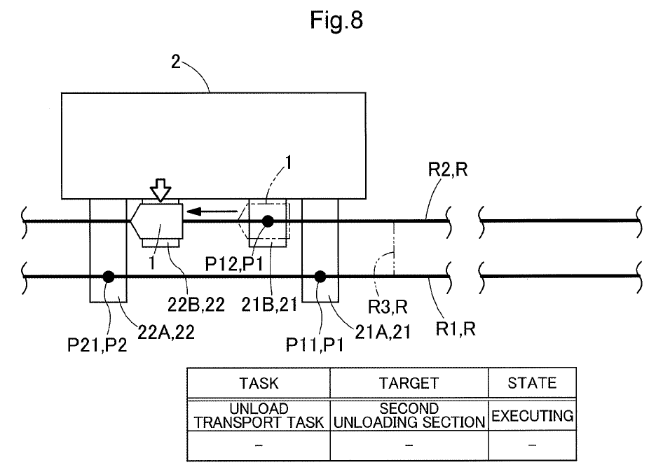

As shown in FIGS. 7 and 8, if the control system 9 determines in the assignment determination processing that the second task is to be assigned to the movable body 1, the control system 9 executes consecutive transport processing for causing the movable body 1 to execute the load transport task and the unload transport task consecutively. In the illustrated example, in the consecutive transport processing, the control system 9 causes the movable body 1 to execute the load transport task for the second loading section 21B, and then causes the movable body 1 to execute the unload transport task for the second unloading section 22B. Although not shown in the drawings, in the load transport task for the second loading section 21B, the movable body 1 moves to the above-mentioned transport origin and receives the article W from the transport origin. It is preferable that the consecutive transport processing is executed without waiting for the waiting time T to elapse.

On the other hand, although not shown in the figure, if the control system 9 determines in the assignment determination processing not to assign the second task (here, the load transport task for the second loading section 21B) to the movable body 1, the control system 9 executes single transport processing. Single transport processing is processing for causing the movable body 1 to execute the first task after the waiting time T has elapsed. In this example, in the single transport processing, the unload transport task for the first unloading section 22A or the unload transport task for the second unloading section 22B is set as the first task. In other words, in the assignment processing, the unload transport task for the second unloading section 22B is assigned to the movable body 1 as the first task, but in the single transport processing, the unload transport task for the first unloading section 22A or the unload transport task for the second unloading section 22B is reassigned to the movable body 1 as the first task. In the single transport processing, it is preferable to assign the first task based on the above-mentioned costs.

In this way, the control system 9 is configured to execute assignment processing, wait processing, assignment determination processing, consecutive transport processing, and single transport processing.

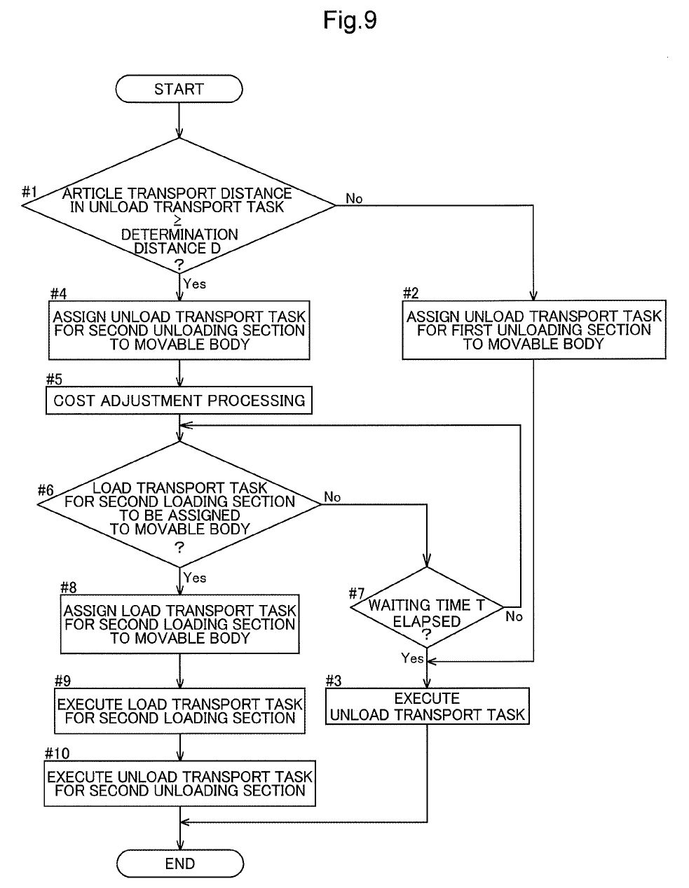

FIG. 9 is a flowchart showing an example of control of the movable body 1 by the control system 9.

As shown in FIG. 9, the control system 9 first determines whether the transport distance of the article W in the unload transport task assigned to the movable body 1 is the determination distance D or more (step #1).

If the transport distance of the article W in the unload transport task is less than the determination distance D, that is, if the distance that the movable body 1 transports the article W in the unload transport task is relatively short (step #1: No), the control system 9 assigns the unload transport task for the first unloading section 22A to the movable body 1 (step #2). Then, the control system 9 causes the movable body 1 to execute the unload transport task for the first unloading section 22A (step #3).

On the other hand, if the transport distance of the article W in the unload transport task is the determination distance D or more, that is, if the distance that the movable body 1 transports the article W in the unload transport task is relatively long (step #1: Yes), the control system 9 assigns the unload transport task for the second unloading section 22B to the movable body 1 (step #4). Then, the control system 9 executes cost adjustment processing for the cost required to execute the load transport task for the second loading section 21B (step #5).

Next, the control system 9 determines whether or not to assign the load transport task for the second loading section 21B to the movable body 1 (step #6).

At this time, if the control system 9 determines that the load transport task for the second loading section 21B is not to be assigned to the movable body 1 (step #6: No), the control system 9 determines whether the waiting time T has elapsed since when the unload transport task for the second unloading section 22B was assigned to the movable body 1 (step #7).

If the waiting time T has elapsed (step #7: Yes), the control system 9 assigns the unload transport task for the first unloading section 22A or the unload transport task for the second unloading section 22B to the movable body 1, and causes the movable body 1 to execute the assigned unload transport task (step #3). On the other hand, if the waiting time T has not elapsed (step #7: No), the control system 9 returns to step #6 above.

If the control system 9 determines that the load transport task for the second loading section 21B is to be assigned to the movable body 1 (step #6: Yes), the control system 9 assigns the load transport task for the second loading section 21B to the movable body 1 (step #8). Then, the control system 9 causes the movable body 1 to execute the load transport task for the second loading section 21B (step #9), and then causes the movable body 1 to execute the unload transport task for the second unloading section 22B (step #10).

In the above flowchart, steps #2 and #4 correspond to assignment processing, step #7 corresponds to wait processing, step #6 corresponds to assignment determination processing, steps #8, #9, and #10 correspond to consecutive transport processing, and step #3 corresponds to single transport processing.

### Other Embodiments

(1) In the above embodiment, an example is described in which the movement route R includes the first layer route R1, the second layer route R2 located above the first layer route R1, and the connecting route R3 that connects the first layer route R1 and the second layer route R2. However, the present invention is not limited to such a configuration, and the movement routes R may be arranged at the same height. In this configuration, the movable body 1 may be an AGV (Automated Guided Vehicle), an RGV (Rail Guided Vehicle), or the like. Furthermore, the movable body 1 may be an unmanned aerial vehicle.
(2) In the above embodiment, an example is given of a configuration in which, in the consecutive transport processing, the second loading section 21B, which is the target of the load transport task, and the second unloading section 22B, which is the target of the unload transport task, belong to the same storage device 2. However, there is no limitation to such a configuration, and for example, when two storage devices 2 are adjacent to each other, in the consecutive transport processing, the second loading section 21B of the storage device 2 on the upstream side in the movement direction M may be the target of the load transport task, and the second unloading section 22B of the storage device 2 on the downstream side in the movement direction M may be the target of the unload transport task.
(3) In the above embodiment, an example is described in which, in the consecutive transport processing, the movable body 1 executes the load transport task and then executes the unload transport task. However, the present invention is not limited to such a configuration, and the movable body 1 may be configured to execute the unload transport task and then execute the load transport task. In this configuration, for example, when two storage devices 2 are adjacent to each other, it is preferable that the movable body 1 executes the unload transport task for the second unloading section 22B of the storage device 2 on the upstream side in the movement direction M, and then executes the load transport task for the second loading section 21B of the storage device 2 on the downstream side in the movement direction M. Furthermore, in the case where the movable body 1 executes the unload transport task for the second unloading section 22B and the load transport task for the second loading section 21B in the same storage device 2, if the transport destination of the unload transport task and the transport origin of the load transport task are relatively close to the storage device 2, for example, after completing the unload transport task, the movable body 1 may travel in reverse toward the second loading section 21B and execute the load transport task.
(4) In the above embodiment, an example is described in which the control system 9 assigns the unload transport task for the second unloading section 22B to the movable body 1 as the first task without taking cost into consideration in the assignment processing. However, the present invention is not limited to such a configuration, and, in the assignment processing, the control system 9 may execute processing to reduce the cost required to execute the first task, and then determine the first task based on the cost.
(5) In the above embodiment, an example is described in which, when executing consecutive transport processing, the unload transport task for the second unloading section 22B is the first task, and the load transport task for the second loading section 21B is the second task. However, the present invention is not limited to such a configuration, and, when executing consecutive transport processing, the load transport task for the second loading section 21B may be the first task, and the unload transport task for the second unloading section 22B may be the second task.
(6) In the above embodiment, an example is described in which the unloading section 22 is disposed downstream of the loading section 21 in the movement direction M. However, the present invention is not limited to such a configuration, and the loading section 21 and the unloading section 22 may be configured as an integrated section used in com
on. (7) In the above embodiment, an example is described in which the control system 9 includes the first control device 91 and the second control devices 92 respectively provided in the movable bodies 1, and the first control device 91 issues commands to the second control devices 92. However, the present invention is not limited to such a configuration, and for example, a configuration may be adopted in which the second control devices 92 operate independently of each other or cooperate with each other.
(8) Note that the configurations disclosed in each of the above-described embodiments can be applied in combination with configurations disclosed in other embodiments, as long as no contradiction arises. Regarding such other configurations as well, the embodiments disclosed in this specification are merely examples in all respects. Therefore, various modifications can be made as appropriate within the scope of the present disclosure.

### Summary of Embodiments

The following describes an overview of the transport facility described above.

A transport facility according to an aspect of the present invention includes:

a movable body configured to transport an article;

a storage device including at least one loading section and at least one unloading section, and configured to store a plurality of articles; and

a control system configured to control the movable body,

the storage device being further configured to receive an article from the movable body via the loading section and store the received article, and transfer the stored article from the unloading section to the movable body,

the control system being further configured to cause the movable body to execute an unload transport task in which the movable body receives an article from the unloading section and transports the received article to a transport destination, and a load transport task in which the movable body transfers, to the loading section, an article received at a transport origin, and

the control system being further configured to execute

assignment processing of assigning a first task, which is a first one of the unload transport task and the load transport task, to the movable body,

wait processing of, after executing the assignment processing, causing the movable body to wait for a predetermined waiting time before executing the first task,

assignment determination processing of, during the waiting time, determining whether or not to assign a second task, which is a second one of the unload transport task and the load transport task, to the movable body,

consecutive transport processing of, in response to the control system determining to assign the second task to the movable body in the assignment determination processing, causing the movable body to execute the load transport task and the unload transport task consecutively, and

single transport processing of, in response to the control system determining not to assign the second task to the movable body in the assignment determination processing, causing the movable body to execute the first task after the waiting time elapses.

According to this configuration, when consecutive transport processing is executed, the movable body can execute the load transport task and the unload transport task consecutively. This makes it easier to shorten the travel distance traveled by the movable body, and to increase the efficiency of transport of articles by the movable body.

Also, the time for which the execution of the first task is put on hold in the wait processing is limited to the waiting time, thereby making it possible to avoid the case where the first task is not executed for a long period of time even when single transport processing is executed. This makes it possible to minimize the decrease in the efficiency of transport of articles by the movable body.

Also, it is preferable that the movable body moves in a predetermined movement direction along a predetermined movement route, and

in the storage device, the unloading section is located downstream of the loading section in the movement direction.

According to this configuration, in the consecutive transport processing, the movable body can deliver an article to the loading section, move in the movement direction, and then receive an article from the unloading section. Therefore, it is easy to shorten the travel distance traveled by the movable body, and it is easy to increase the efficiency of transport of articles by the movable body.

Also, it is preferable that the first task is the unload transport task, and

in a case where the transport destination of the received article in the unload transport task is another storage device, the waiting time is set longer than in a case where the transport destination is a processing device that performs article processing.

According to this configuration, in the case where the transport destination of an article in the unload transport task is another storage device, there is little need to rush the transport of the article, and therefore by setting the waiting time to a relatively long time, it is easier to improve the efficiency of the transport of articles by the movable body. On the other hand, in the case where the transport destination of the article in the unload transport task is a processing device, by setting the waiting time to a relatively short time, it is possible to allow the article to be transported to the processing device quickly, making it easier to improve the operating efficiency of the processing device.

Also, it is preferable that the control system assigns the unload transport task and the load transport task to the movable body in such a manner as to minimize a cost set based on movement of the movable body and operations of the movable body including transfer of an article to the loading section and reception of an article from the unloading section, and

during the waiting time, the control system executes cost adjustment processing of setting the cost required to execute the second task lower than that during a time excluding the waiting time.

According to this configuration, in the cost adjustment processing, the cost required to execute the second task during the waiting time is set lower than the time excluding the waiting time, thereby making it possible to increase the possibility that the second task is assigned to the movable body during the waiting time. Therefore, the possibility of executing consecutive transport processing is increased, and in turn, the efficiency of the transport of articles by the movable body is easily increased.

Also, it is preferable that the movable body travels along a predetermined movement route, stops at at least one transfer position predetermined on the movement route, and performs article transfer with a processing device at the at least one transfer position,

the movement route includes a first layer route, a second layer route located above the first layer route, and a connecting route connecting the first layer route and the second layer route,

the at least one loading section includes a first loading section at which article transfer is performed with the movable body located on the first layer route, and a second loading section at which article transfer is performed with the movable body located on the second layer route,

the at least one unloading section includes a first unloading section at which article transfer is performed with the movable body located on the first layer route, and a second unloading section at which article transfer is performed with the movable body located on the second layer route,

the at least one transfer position is set such that fewer transfer position is set on the second layer route than on the first layer route,

in the assignment processing, the control system executes the wait processing in a case where the first task is the unload transport task for the second unloading section or the load transport task for the second loading section, and

in the assignment processing, the control system does not execute the wait processing in a case where the first task is the unload transport task for the first unloading section or the load transport task for the first loading section.

Generally, the second layer route, which has fewer transfer positions than the first layer route, is mainly used by movable bodies that perform transport tasks that have relatively long transport distances. Therefore, according to the above configuration, wait processing can be executed when executing a transport task having a relatively long transport distance, such as the unload transport task for the second unloading section at which article transfer is performed with a movable body located on the second layer route, or the load transport task for the second loading section at which article transfer is performed with a movable body located on the second layer route. On the other hand, it is possible to not execute wait processing when executing a transport task with a relatively short transport distance, such as the unload transport task for the first unloading section at which article transfer is performed with a movable body located on the first layer route, or the load transport task for the first loading section at which article transfer is performed with a movable body located on the first layer route. In other words, when the transport distance is relatively long, the movable body waits for a second task to be assigned in the wait processing, and if a second task is assigned to the movable body during the waiting time, consecutive transport processing can be executed, thereby improving the efficiency of the transport of articles by the movable body. When the transport distance is relatively short, the first task can be executed without waiting for assignment of a second task, thereby making it possible to realize quick article transport.

Also, it is preferable that in response to an article transport distance in the unload transport task being a predetermined determination distance or more,

in the assignment processing, the control system sets the first task to the unload transport task for the second unloading section,

in the assignment determination processing, the control system sets the second task to the load transport task for the second loading section,

in the consecutive transport processing, the control system causes the movable body to execute the load transport task for the second loading section and thereafter causes the movable body to execute the unload transport task for the second unloading section, and

in the single transport processing, the control system sets the first task to the unload transport task for the first unloading section or the unload transport task for the second unloading section, and

in response to the article transport distance in the unload transport task being less than the determination distance, in the assignment processing, the control system sets the first task to the unload transport task for the first unloading section.

According to this configuration, when the article transport distance in transport performed by the movable body is the determination distance or more, in the consecutive transport processing, it is possible to cause the movable body to execute the load transport task for the second loading section and thereafter execute the unload transport task for the second unloading section. In other words, when the article transport distance in transport performed by the movable body is the determination distance or more, it is possible to increase the possibility that the movable body travels along the second layer route. Here, since the second layer route has fewer transfer positions than the first layer route, when the movable body travels along the second layer route, the movable body can be caused to efficiently perform transport over a relatively long distance.

### INDUSTRIAL APPLICABILITY

The technology disclosed herein can be used in a transport facility that includes a movable body that transports an article, a storage device that stores a plurality of articles, and a control system that controls the movable body.

What is claimed is:

1. A transport facility comprising:
a movable body configured to transport an article;
a storage device comprising at least one loading section and at least one unloading section, and configured to store a plurality of articles; and
a control system configured to control the movable body, and
wherein:
the storage device is further configured to receive an article from the movable body via the loading section and store the received article, and transfer the stored article from the unloading section to the movable body,
the control system is further configured to cause the movable body to execute an unload transport task wherein the movable body receives an article from the unloading section and transports the received article to a transport destination, and a load transport task wherein the movable body transfers, to the loading section, an article received at a transport origin, and
the control system is further configured to execute:
assignment processing of assigning a first task, which is a first one of the unload transport task and the load transport task, to the movable body,
wait processing of, after executing the assignment processing, causing the movable body to wait for a predetermined waiting time before executing the first task,
assignment determination processing of, during the waiting time, determining whether or not to assign a second task, which is a second one of the unload transport task and the load transport task, to the movable body,
consecutive transport processing of, in response to the control system determining to assign the second task to the movable body in the assignment determination processing, causing the movable body to execute the load transport task and the unload transport task consecutively, and
single transport processing of, in response to the control system determining not to assign the second task to the movable body in the assignment determination processing, causing the movable body to execute the first task after the waiting time elapses.

2. The transport facility according to claim 1, wherein:
the movable body moves in a predetermined movement direction along a predetermined movement route, and
in the storage device, the unloading section is located downstream of the loading section in the movement direction.

3. The transport facility according to claim 1, wherein:
the first task is the unload transport task, and
in a case where the transport destination of the received article in the unload transport task is another storage device, the waiting time is set longer than in a case where the transport destination is a processing device that performs article processing.

4. The transport facility according to claim 1, wherein:
the control system assigns the unload transport task and the load transport task to the movable body in such a manner as to minimize a cost set based on movement of the movable body and operations of the movable body comprising transfer of an article to the loading section and reception of an article from the unloading section, and
during the waiting time, the control system executes cost adjustment processing of setting the cost required to execute the second task lower than that during a time excluding the waiting time.

5. The transport facility according to claim 1, wherein:
the movable body travels along a predetermined movement route, stops at at least one transfer position predetermined on the movement route, and performs article transfer with a processing device at the at least one transfer position,
the movement route comprises a first layer route, a second layer route located above the first layer route, and a connecting route connecting the first layer route and the second layer route,
the at least one loading section comprises a first loading section at which article transfer is performed with the movable body located on the first layer route, and a second loading section at which article transfer is performed with the movable body located on the second layer route,
the at least one unloading section comprises a first unloading section at which article transfer is performed with the movable body located on the first layer route, and a second unloading section at which article transfer is performed with the movable body located on the second layer route,
the at least one transfer position is set such that fewer transfer position is set on the second layer route than on the first layer route,
in the assignment processing, the control system executes the wait processing in a case where the first task is the unload transport task for the second unloading section or the load transport task for the second loading section, and
in the assignment processing, the control system does not execute the wait processing in a case where the first task is the unload transport task for the first unloading section or the load transport task for the first loading section.

6. The transport facility according to claim 5, wherein:
in response to an article transport distance in the unload transport task being a predetermined determination distance or more,
in the assignment processing, the control system sets the first task to the unload transport task for the second unloading section,
in the assignment determination processing, the control system sets the second task to the load transport task for the second loading section,
in the consecutive transport processing, the control system causes the movable body to execute the load transport task for the second loading section and thereafter causes the movable body to execute the unload transport task for the second unloading section, and
in the single transport processing, the control system sets the first task to the unload transport task for the first unloading section or the unload transport task for the second unloading section, and
in response to the article transport distance in the unload transport task being less than the determination distance, in the assignment processing, the control system sets the first task to the unload transport task for the first unloading section.
